(19) United States
(12) Patent Application Publication
(10) Pub. No.: US 2006/0134878 A1
(43) Pub. Date: Jun. 22, 2006

(54) Method of fabricating metal-insulator-metal capacitor

(76) Inventor: Tae Woo Kim, Icheon city (KR)

Correspondence Address: MCKENNA LONG & ALDRIDGE LLP, 1900 K STREET, NW, WASHINGTON, DC, 20006, US

(21) Appl. No.: 11/300,437

(22) Filed: Dec. 15, 2005

(30) Foreign Application Priority Data
Dec. 16, 2004 (KR) P 2004-0106873

(51) Int. Cl. H01L 21/02

(52) U.S. Cl. 438/393

(57) ABSTRACT

A method for fabricating a metal-insulator-metal (MIM) capacitor includes providing a semiconductor substrate having a region where the metal-insulator-metal capacitor is formed; forming an insulating film on the substrate; forming a sacrificial insulating film on the insulating film; forming a mask pattern having a plurality of openings on the sacrificial insulating film that exposes a surface of the sacrificial insulating film within the region where the metal-insulator-metal capacitor is formed; and forming a plurality of sacrificial insulating film patterns by etching using the mask pattern as an etch mask that expose a surface of the insulating film within the region where the metal-insulator-metal capacitor is formed.

### CROSS-REFERENCE TO RELATED APPLICATIONS

This application claims the benefit of Korean Patent Application No. 10-2004-0106873, filed on Dec. 16, 2004, which is hereby incorporated by reference for all purposes as if fully set forth herein.

### BACKGROUND OF THE INVENTION

1. Field of the Invention

The present invention relates to semiconductor devices, and more particularly to a method of fabricating a metal-insulator-metal capacitor whose capacitance can be increased without increasing the area occupied by the capacitor.

2. Discussion of the Related Art

Metal-insulator-metal (MIM) capacitors are becoming more popular for use in practical applications. MIM capacitors have better voltage (Vcc) characteristics and mismatching characteristics than conventional polysilicon-insulator-polysilicon (PIP) capacitors. MIM capacitors are conventionally designed to have a capacitance of 1 fF/μm². However, there is a growing demand for MIM capacitors having a higher capacitance in various application fields, including analog-to-digital converters, switching capacitor filters, mixed-signal technologies, and radio frequency technologies.

FIGS. 1-4 illustrate a method for fabricating a related art metal-insulator-metal capacitor.

As shown first in FIG. 1, an insulating film 110 is formed on a semiconductor substrate 100. A bottom metal electrode film 120, a dielectric film 130 and a top metal electrode film 140 are sequentially layered on the insulating film 110. The insulating film 110 may be an interlayer insulating film or an intermetallic insulating film.

As shown in FIG. 2, portions of the top metal electrode film 140 and the dielectric film 130 are sequentially removed by etching using a first etch mask pattern (not shown) to leave a dielectric film pattern 131 and a top metal electrode film pattern 141 on a region of the surface of the bottom metal electrode film 120.

As shown in FIG. 3, portions of the bottom metal electrode film 120 are removed by etching using a second etch mask pattern (not shown) to leave a bottom metal electrode film pattern 121 on a region of the surface of the insulating film 110. The bottom metal electrode film pattern 121, the dielectric film pattern 131 and the top metal electrode film pattern 141 arranged in this order on the insulating film 110 constitute an MIM capacitor.

As shown in FIG. 4, an intermetallic insulating film 150 is formed on the insulating film 110 so as to cover the MIM capacitor. A first metal interconnection film 161 is formed so as to electrically connect to the top metal electrode film pattern 141 through the intermetallic insulating film 150. Also, a second metal interconnection film 162 is formed so as to electrically connect to the bottom metal electrode film pattern 121 through the intermetallic insulating film 150.

The related art method involves a total of five masking steps and twelve other processing steps to fabricate the conventional MIM capacitor. Despite this number of complex processing steps, an increase in the overall area of the MIM capacitor is required to increase the capacitance. Therefore, the method is not suitable for use in application fields requiring a high degree of integration.

### SUMMARY OF THE INVENTION

Accordingly, the present invention is directed to a method of fabricating a metal-insulator-metal capacitor that substantially obviates one or more problems due to limitations and disadvantages of the related art.

An advantage of the present invention is that it can provide a method of fabricating a MIM capacitor with a reduced number of processing steps.

Another advantage of the present invention is that it can provide a method of fabricating a MIM capacitor whose capacitance can be increased without increasing the overall area of the capacitor.

Additional features and advantages of the invention will be set forth in the description which follows, and in part will be apparent from the description, or may be learned by practice of the invention. The objectives and other advantages of the invention will be realized and attained by the method particularly pointed out in the written description and claims hereof as well as the appended drawings.

To achieve these and other advantages and in accordance with the purpose of the invention, as embodied and broadly described, a method of fabricating a metal-insulator-metal capacitor comprises providing a semiconductor substrate having a region where the metal-insulator-metal capacitor is formed; forming an insulating film on the substrate; forming a sacrificial insulating film on the insulating film; forming a mask pattern having a plurality of openings on the sacrificial insulating film that exposes a surface of the sacrificial insulating film within the region where the metal-insulator-metal capacitor is formed; and forming a plurality of sacrificial insulating film patterns by etching using the mask pattern as an etch mask that expose a surface of the insulating film within the region where the metal-insulator-metal capacitor is formed.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate embodiment(s) of the invention and together with the description serve to explain the principles of the invention. In the drawings:

FIGS. 1-4 are cross-sectional views illustrating a method of fabricating a related art metal-insulator-metal capacitor; and

FIGS. 5-8 are cross-sectional views illustrating a method of fabricating a metal-insulator-metal capacitor according to the present invention.

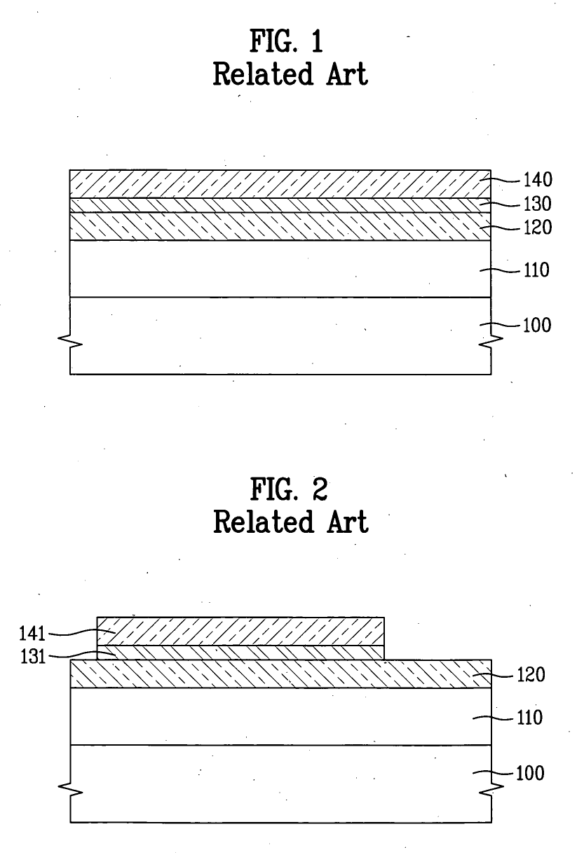

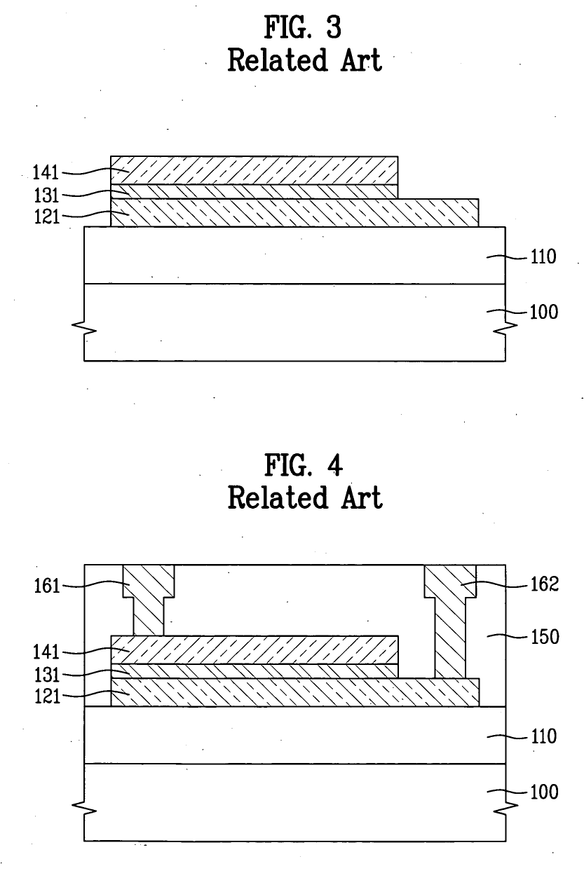

### DETAILED DESCRIPTION OF THE INVENTION

Reference will now be made in detail to exemplary embodiments of the present invention, examples of which are illustrated in the accompanying drawings. Wherever possible, like reference designations will be used throughout the drawings to refer to the same or similar parts.

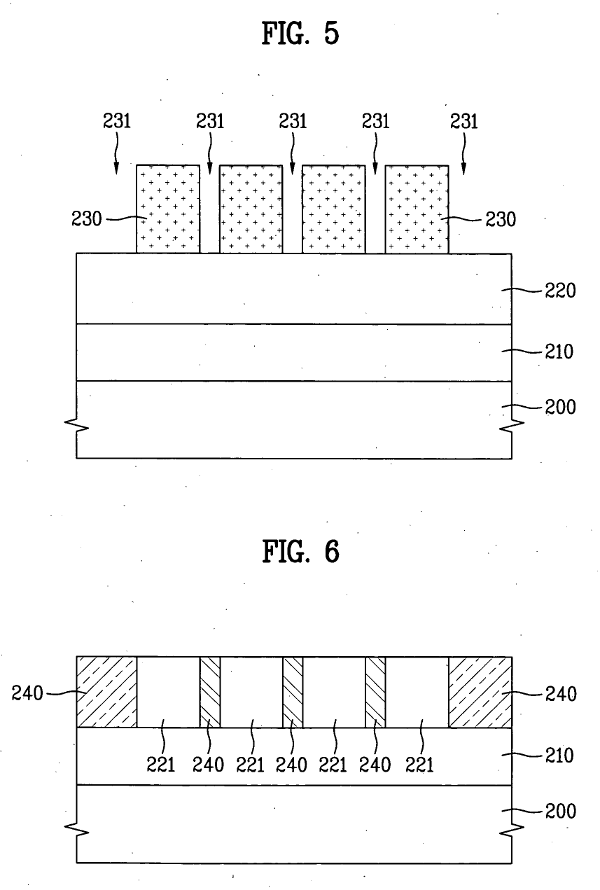

FIGS. 5-8 illustrate steps of a method of fabricating a metal-insulator-metal capacitor according to the present invention.

Referring to FIG. 5, an insulating film 210 is formed on a semiconductor substrate 200. A sacrificial insulating film 220 is formed on the insulating film 210. The semiconductor substrate 200 may be made of silicon. The insulating film 210 may be an interlayer insulating film or an intermetallic insulating film. If the insulating film 210 is an intermetallic insulating film, metal interconnection films at low levels may be disposed under the insulating film. The sacrificial insulating film 220 can act as an interlayer insulating film or an intermetallic insulating film in regions other than the region where the MIM capacitor is formed. The sacrificial insulating film 220 may be composed of an oxide film. After forming the sacrificial insulating film 220, a photoresist film pattern 230 is formed on the sacrificial insulating film 220. The photoresist film pattern 230 acts as a mask pattern. The photoresist film pattern 230 has a plurality of openings 231 through which the sacrificial insulating film 220 is exposed within the region where the MIM capacitor is formed.

Referring to FIG. 6, the exposed portions of the sacrificial insulating film 220 are removed by etching using the photoresist film pattern 230 as an etch mask. Accordingly, a plurality of sacrificial insulating film patterns 221 remain. A surface of the insulating film 210 is exposed through the sacrificial insulating film patterns 221 within the region where the MIM capacitor is formed. The etching for forming the sacrificial insulating film patterns 221 may be dry etching, such as reactive ion etching. A metal film (not shown) is formed over the entire surface of the resulting structure to form bottom metal electrode film patterns that fill the spaces between the sacrificial insulating film patterns 221. The surface of the sacrificial insulating film patterns 221 is planarized until it is exposed to form bottom metal electrode film patterns 240 between the sacrificial insulating film patterns 221. The planarization may be performed by chemical-mechanical polishing. Alternatively, the bottom metal electrode film patterns 240 can be formed by a common damascene process.

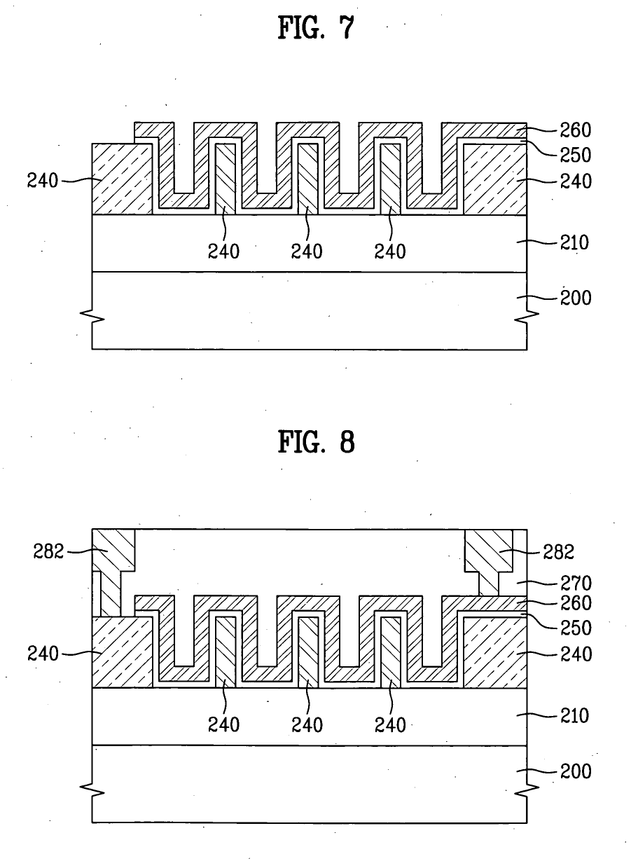

Referring to FIG. 7, the sacrificial insulating film patterns 221 are removed to expose the surface of the insulating film 210 between the bottom metal electrode film patterns 240. When the sacrificial insulating film 220 is used as an interlayer insulating film or an intermetallic insulating film, the sacrificial insulating film patterns 221 are removed in regions other than the region where the MIM capacitor is formed only after formation of a mask pattern (not shown) that only exposes the region where the MIM capacitor is formed. Subsequently, a dielectric film 250 and a top metal electrode film 260 are sequentially layered on the exposed surface of the bottom metal electrode film patterns 240 and the insulating film 210 to form the MIM capacitor. The dielectric film 250 and the top metal electrode film 260 may be irregular.

Referring to FIG. 8, an intermetallic insulating film 270 is formed over the entire surface of the resulting structure shown in FIG. 7. A common via formation process is performed to form first and second metal interconnection films 282 that electrically connect to the bottom metal electrode film pattern 240 and the top metal electrode film 260, respectively, through the intermetallic insulating film 270.

Since the bottom metal electrode film patterns can be formed by a common damascene process, one masking step and three other processing steps can be eliminated. In addition, MIM capacitors having a high capacitance can advantageously be fabricated without an increase in the area occupied by the capacitors.

It will be apparent to those skilled in the art that various modifications and variation can be made in the present invention without departing from the spirit or scope of the invention. Thus, it is intended that the present invention cover the modifications and variations provided they come within the scope of the appended claims and their equivalents.

What is claimed is:

1. A method for fabricating a metal-insulator-metal capacitor, comprising:
providing a semiconductor substrate having a region where the metal-insulator-metal capacitor is formed;
forming an insulating film on the substrate;
forming a sacrificial insulating film on the insulating film;
forming a mask pattern having a plurality of openings on the sacrificial insulating film that exposes a surface of the sacrificial insulating film within the region where the metal-insulator-metal capacitor is formed; and
forming a plurality of sacrificial insulating film patterns by etching using the mask pattern as an etch mask that expose a surface of the insulating film within the region where the metal-insulator-metal capacitor is formed.

2. The method according to claim 1, further comprising:
forming a plurality of bottom metal electrode film patterns by filling spaces between the sacrificial insulating film patterns with a metal film; and
removing the sacrificial insulating film patterns to expose a surface of the insulating film between the bottom metal electrode film patterns.

3. The method according to claim 1, further comprising:
forming a dielectric film on the surface of the bottom metal electrode film patterns and the insulating film; and
forming a top metal electrode film on the dielectric film.

4. The method according to claim 2, further comprising:
forming a dielectric film on the surface of the bottom metal electrode film patterns and the insulating film; and
forming a top metal electrode film on the dielectric film.

5. The method according to claim 1, wherein the sacrificial insulating film is composed of an oxide film.

6. The method according to claim 1, wherein forming a plurality of sacrificial insulating film patterns by etching is performed by dry etching.

7. The method according to claim 6, wherein the dry etching is reactive ion etching.

8. The method according to claim 2, wherein removing the sacrificial insulating film patterns is performed by etching using an etch mask pattern to expose only the region where the metal-insulator-metal capacitor is formed.

9. The method according to claim 2, wherein forming a plurality of bottom metal electrode film patterns comprises:
forming a metal film over an entire surface of the structure in which the sacrificial insulating film patterns are formed; and
planarizing the metal film until a top surface of the sacrificial insulating film patterns is exposed.

10. The method according to claim 9, wherein planarizng the metal film is performed by chemical-mechanical polishing.

11. The method according to claim 2, wherein the plurality of bottom metal electrode film patterns are formed by a common damascene process.

12. The method according to claim 3, further comprising:
forming an intermetallic insulating film to cover the metal-insulator-metal capacitor including the dielectric film and the top metal electrode film; and
forming a first metal interconnection film and a second metal interconnection film that electrically connect to the bottom metal electrode film pattern and the top metal electrode film, respectively, through the intermetallic insulating film.

13. The method according to claim 4, further comprising:
forming an intermetallic insulating film to cover the metal-insulator-metal capacitor including the dielectric film and the top metal electrode film; and
forming a first metal interconnection film and a second metal interconnection film that electrically connect to the bottom metal electrode film pattern and the top metal electrode film, respectively, through the intermetallic insulating film.

14. The method according to claim 1, wherein the insulating film is an interlayer insulating film.

15. The method according to claim 1, wherein the insulating film is an intermetallic insulating film.
